(19) United States
(12) Patent Application Publication
(10) Pub. No.: US 2023/0295398 A1
(43) Pub. Date: Sep. 21, 2023

(54) THERMALLY CONDUCTIVE SHEET AND DEVICE PROVIDED WITH THERMALLY CONDUCTIVE SHEET

(71) Applicant: SHOWA DENKO MATERIALS CO., LTD., Tokyo (JP)

(72) Inventors: Mika KOBUNE, Tokyo (JP); Michiaki YAJIMA, Tokyo (JP)

(21) Appl. No.: 18/013,754

(22) PCT Filed: Jul. 8, 2020
(86) PCT No.: PCT/JP2020/030463

§ 371 Date: Dec. 29, 2022

(51) Int. Cl. C08K 3/04; C08J 5/18; H01L 23/373; H05K 7/20

(52) U.S. Cl. CPC C08K 3/042; C08J 5/18; H01L 23/3731; H01L 23/3735; H05K 7/20481; C08J 2323/22; C08K 2201/001; C08J 2333/10

(57) ABSTRACT

One embodiment of the present invention relates to a thermally conductive sheet containing graphite particles (A) including at least one selected from the group consisting of flake-like particles, ellipsoidal particles, and cylindrical particles, in which the graphite particles (A) are oriented in a thickness direction, and a thickness compression ratio is 24% or more at a temperature of 150° C. and a compressive stress of 0.14 MPa.

### TECHNICAL FIELD

The present disclosure relates to a thermally conductive sheet, a device provided with the thermally conductive sheet, and a method of manufacturing the device provided with the thermally conductive sheet.

### BACKGROUND ART

As electronic devices become denser and thinner, it has become necessary for electronic components such as semiconductor elements and semiconductor devices to have good heat dissipation properties, in other words, to be able to efficiently dissipate generated heat. For example, semiconductor devices have a configuration in which a heat generating body such as a semiconductor element and a heat dissipating body of aluminum, copper, or the like are closely adhered with a thermally conductive sheet arranged therebetween, thereby allowing heat to propagate from the heat generating body to the heat dissipating body.

Patent Literature 1 describes a thermally conductive sheet that contains graphite particles, in which the elastic modulus is 1.4 MPa or less when a compressive stress is 0.1 MPa at 150° C., and the tack force is 5.0 N·mm or more at 25° C.

### CITATION LIST

### Patent Literature

Patent Literature 1: International Publication No. 2019/159340

### SUMMARY OF THE INVENTION

### Technical Problem

In recent years, as electronic devices have become even denser and thinner, the thicknesses of heat generating bodies and heat dissipating bodies have also tended to decrease. It is desired for the thermally conductive sheets that adhere these elements to exhibit good thermal conductivity even when a heat generating body and a heat dissipating body are adhered with low pressure.

Thus, the present disclosure provides a thermally conductive sheet having improved thermal conductivity. Furthermore, the present disclosure provides a device provided with the thermally conductive sheet having improved thermal conductivity. In addition, the present disclosure provides a method of manufacturing the device provided with the thermally conductive sheet having improved thermal conductivity.

### Solution to Problem

Various embodiments are included in the present invention. Examples of embodiments are given below. The present invention is not limited to the embodiments below.

One embodiment relates to a thermally conductive sheet containing graphite particles (A) including at least one selected from the group consisting of flake-like particles, ellipsoidal particles, and cylindrical particles, in which the graphite particles (A) are oriented in a thickness direction, and a thickness compression ratio is 24% or more at a temperature of 150° C. and a compressive stress of 0.14 MPa.

Another embodiment relates to a thermally conductive sheet containing graphite particles (A) including at least one selected from the group consisting of flake-like particles, ellipsoidal particles, and cylindrical particles, in which the graphite particles (A) are oriented in a thickness direction, and a mean particle diameter of the graphite particles (A) is 50 to 75% of a thickness.

Another embodiment relates to a device including a heat generating body, a heat dissipating body, and the thermally conductive sheet according to any of the aforementioned embodiments in contact with the heat generating body and the heat dissipating body.

Another embodiment relates to a method of manufacturing a device, including: arranging the thermally conductive sheet according to any of the aforementioned embodiments to be between a heat generating body and a heat dissipating body, and obtaining a composite body including the heat generating body, the heat dissipating body, and the thermally conductive sheet in contact with the heat generating body and the heat dissipating body; and applying pressure in a thickness direction of the thermally conductive sheet to the composite body, and adhering the heat generating body and the heat dissipating body via the thermally conductive sheet.

### Advantageous Effects of the Invention

According to the present disclosure, a thermally conductive sheet having improved thermal conductivity is provided. Furthermore, according to the present disclosure, a device provided with the thermally conductive sheet having improved thermal conductivity is provided. In addition, according to the present disclosure, a method of manufacturing the device provided with the thermally conductive sheet having improved thermal conductivity is provided.

### DESCRIPTION OF EMBODIMENTS

Embodiments of the present invention will be described. The present invention is not limited to the embodiments below. The following embodiments can be implemented individually or in combination.

### <Thermally Conductive Sheet>

A thermally conductive sheet contains graphite particles (A) including at least one selected from the group consisting of flake-like particles, ellipsoidal particles, and cylindrical particles. In the thermally conductive sheet, the graphite particles (A) are oriented in the thickness direction of the thermally conductive sheet.

In some embodiments, in the thermally conductive sheet, a thickness compression ratio of the thermally conductive sheet is 24% or more at a temperature of 150° C. and a compressive stress of 0.14 MPa. Alternatively, in some embodiments, the thermally conductive sheet is used to adhere a heat generating body and a heat dissipating body via the thermally conductive sheet, and therefore the compression ratio is 24% or more at the temperature and compressive stress produced when the heat generating body and the heat dissipating body are adhered via the thermally conductive sheet.

In some embodiments, in the thermally conductive sheet, the ratio of the mean particle diameter of the graphite particles (A) is 50 to 75% with respect to the thickness of the thermally conductive sheet.

### [Components]

The thermally conductive sheet contains at least graphite particles (A). The thermally conductive sheet may further contain optional components such as a resin.

### (Graphite Particles (A))

The graphite particles (A) include at least one selected from the group consisting of flake-like particles, ellipsoidal particles, and cylindrical particles. From the viewpoint of improving thermal conductivity, the graphite particles (A) preferably include flake-like particles. Flake-like particles have a tendency of being easily oriented in a desired direction within a thermally conductive sheet. From the viewpoint of high crystallinity, the graphite particles (A) preferably include flake-like expanded graphite particles, which are obtained by grinding expanded graphite that is in the form of a sheet.

In the thermally conductive sheet, the graphite particles (A) are oriented in the thickness direction of the thermally conductive sheet. “The graphite particles (A) are oriented in the thickness direction of the thermally conductive sheet” refers to a state where, preferably, the angle formed between the graphite particles (A) and the surface (main surface) of the thermally conductive sheet is 60° or more. In the present disclosure, this angle is sometimes referred to as the “orientation angle”. The orientation angle may be 80° or more, 85° or more, or 88° or more. The orientation angle can be measured using the following method, for example.

The thermally conductive sheet is cut to obtain a cross section. The thermally conductive sheet is cut in such a way that the orientation angle can be measured. For example, if the thermally conductive sheet contains flake-like particles, the thermally conductive sheet is cut such that the cross section of the thermally conductive sheet includes a cross section that is perpendicular (or substantially perpendicular) to the plane direction of the flake-like particles. Next, the cross section of the thermally conductive sheet is observed using an SEM (scanning electron microscope), and the orientation angle is measured for any 50 graphite particles (A). A total of 50 graphite particles (A) may be selected from one cross section of the thermally conductive sheet, or a total of 50 graphite particles (A) may be selected from two or more cross sections of the thermally conductive sheet. In the case of flake-like particles, the angle formed between the thermally conductive sheet thickness direction of the plane of the flake-like particles (in other words, the longitudinal direction of the cross section of the flake-like particles) and the surface of the thermally conductive sheet is measured. In the case of ellipsoidal particles, the angle formed between the major axis direction of the ellipsoidal particles and the surface of the thermally conductive sheet is measured. In the case of cylindrical particles, the angle formed between the major axis direction of the cylindrical particles and the surface of the thermally conductive sheet is measured. The arithmetic mean value of the obtained measurement values (50 items) is taken as the orientation angle of the graphite particles (A).

The mean particle diameter of the graphite particles (A) is, for example, 50 μm or more, 60 μm or more, 70 μm or more, or 80 μm or more. The mean particle diameter of the graphite particles (A) is, for example, 300 μm or less, 200 μm or less, or 180 μm or less. The mean particle diameter of the graphite particles can be measured using the following method, for example.

Components other than the graphite particles (A) contained in the thermally conductive sheet are removed by dissolving in an organic solvent, and the graphite particles (A) are recovered. The recovered graphite particles (A) are washed using an organic solvent and then dried thoroughly. Using an SEM (scanning electron microscope), any 200 particles are selected from the graphite particles (A), and the particle diameter of each particle is measured. The major diameter of the plane is measured in the case of flake-like particles, the major axis is measured in the case of ellipsoidal particles, and the major axis is measured in the case of cylindrical particles. The arithmetic mean value of the obtained measurement values (200 items) is taken as the mean particle diameter of the graphite particles (A).

A six-membered ring within the crystal of the graphite particles (A) is preferably oriented such that the plane direction of the six-membered ring is the same as the plane direction in the case where the graphite particles (A) are flake-like particles, the major axis direction in the case of ellipsoidal particles, or the major axis direction in the case of cylindrical particles. The plane of a six-membered ring is a plane including a six-membered ring in a hexagonal crystal system, and means a (0001) crystal plane.

Whether the six-membered ring within the crystal of the graphite particles (A) is oriented as described above can be confirmed by X-ray diffraction measurement. Specifically, confirmation can be performed using the following method. In the following, the case where the graphite particles (A) are flake-like particles will be described as an example.

First, a sample sheet for measurement is produced. The sample sheet contains flake-like particles, and the flake-like particles are oriented such that the plane direction thereof is the same direction as the plane direction of the sheet. An example of a method of producing the sample sheet for measurement is as follows.

A mixture of a resin and flake-like particles (graphite particles (A)) is prepared, the flake-like particles being in an amount greater than or equal to 10% by volume relative to the volume of the resin, and the mixture is used to produce a sheet. The “resin” used here is not particularly limited provided that the resin is a material that does not exhibit peaks that interfere with X-ray diffraction measurement, and is a material with which a sheet can be formed. Specifically, it is possible to use an amorphous resin that has cohesion as a binder such as acrylic rubber, NBR (acrylonitrile butadiene rubber), and SIBS (styrene-isobutylene-styrene copolymer).

A sheet of the mixture is pressed to become 1/10 or less of its original thickness, and a plurality of pressed sheets are layered to form a layered body. The layered body is further pressed down to become 1/10 or less. These operations are repeated three or more times to obtain a sample sheet for measurement. Within the obtained sample sheet for measurement, a state in reached in which it can be said that the plane direction of the flake-like particles is the same direction as the plane direction of the sample sheet for measurement.

Thereafter, X-ray diffraction measurement is performed on the surface of the sample sheet for measurement. The height H₁ of a peak corresponding to the (110) plane of graphite that appears near 2θ=77° and the height H₂ of a peak corresponding to the (002) plane of graphite that appears near 20=27° are measured. If the value (H₁/H₂) obtained by dividing H₁ by H₂ is 0 to 0.02, it is determined that the plane direction of the six-membered ring is oriented in the same direction as the plane direction of the flake-like particles. CuKα can be used for the X-ray source.

A six-membered ring of the ellipsoidal particles and a six-membered ring of the cylindrical particles can be confirmed in the same manner as described above, with the exception that “the plane direction of the flake-like particles” is changed to “the major axis direction of the ellipsoidal particles” or “the major axis direction of the cylindrical particles”.

From the above, “a six-membered ring within the crystal of the graphite particles (A) is oriented such that the plane direction of the six-membered ring is the same as the plane direction in the case where the graphite particles (A) are flake-like particles, the major axis direction in the case of ellipsoidal particles, or the major axis direction in the case of cylindrical particles” refers to a state where, preferably, an X-ray diffraction measurement is performed on the surface of a sample sheet for measurement containing the graphite particles (A), and the value obtained by dividing the height of the peak corresponding to the (110) plane of the graphite particles (A) that appears near 2θ=77° by the height of the peak corresponding to the (002) plane of the graphite particles (A) that appears near 2θ=27° is 0 to 0.02.

In the present disclosure, an X-ray diffraction measurement can be performed under the following conditions, for example.
Device: “D8DISCOVER” manufactured by Bruker AXS Corporation
X-ray source: CuKα at a wavelength of 1.5406 nm, 40 kV, 40 mA
Step (measurement step width): 0.01°
Step time: 720 sec

The content of the graphite particles (A) in the thermally conductive sheet is, for example, preferably 15 to 50% by volume, more preferably 20 to 45% by volume, and even more preferably 25 to 40% by volume from the viewpoint of balance between thermal conductivity and adhesiveness. When the content of the graphite particles (A) is 15% by volume or more, there is a tendency for thermal conductivity to improve. Furthermore, when the content of the graphite particles (A) is 50% by volume or less, there is a tendency for it to be possible to suppress a decline in tackiness and adhesiveness.

The content (% by volume) of the graphite particles (A) can be obtained using the following formula, for example. The content (% by volume) of components other than the graphite particles (A) contained in the thermally conductive sheet can be obtained using the same method.

Content (% by volume) of graphite particles(A)=[(Aw/Ad)/{(Aw/Ad)+(Bw/Bd)+(Cw/Cd)+(Dw/Dd)+(Ew/Ed)+(Xw/Xd)}]×100
Aw: Mass composition (% by mass) of graphite particles (A)
Bw: Mass composition (% by mass) of a polymer (B) that is liquid at 25° C.
Cw: Mass composition (% by mass) of a polymer (C) that has a glass transition temperature of 20° C. or less
Dw: Mass composition (% by mass) of a hot melt agent (D)
Ew: Mass composition (% by mass) of an antioxidant (E)
Xw: Mass composition (% by mass) of other optional components
Ad: Density (g/cm³) of graphite particles (A) (Ad is taken as 2.1 g/cm³ in the present disclosure)
Bd: Density (g/cm³) of a polymer (B) that is liquid at 25° C.
Cd: Density (g/cm³) of a polymer (C) that has a glass transition temperature of 20° C. or lower
Dd: Density (g/cm³) of a hot melt agent (D)
Ed: Density (g/cm³) of an antioxidant (E)
Xd: Density (g/cm³) of other optional components

Note that the mass composition is the mass percentage (% by mass) based on the total mass of all components contained in the thermally conductive sheet. Furthermore, in a case where the thermally conductive sheet contains two or more “other optional components”, “Xw/Xd” is calculated for each component and all are added to the denominator.

The graphite particles (A) may include graphite particles other than flake-like particles, ellipsoidal particles, and cylindrical particles. Examples of graphite particles other than flake-like particles, ellipsoidal particles, and cylindrical particles include spherical graphite particles, artificial graphite particles, thinned graphite particles, acid-treated graphite particles, expanded graphite particles, carbon fiber flakes, and the like.

### (Optional Components Such as Resins)

The thermally conductive sheet may contain optional components such as resins. The thermally conductive sheet may contain one resin or two or more resins. Resins include at least one selected from the group consisting of thermosetting resins and thermoplastic resins, for example. Resins, specifically, may include at least one selected from the group consisting of acrylic resins, epoxy resins, acrylonitrile resins, bismaleimide resins, benzocyclobutene resins, phenol resins, diallyl phthalate resins, terpene resins, petroleum resins, polyolefins, conjugated diene polymers, silicones, polyesters, polyurethanes, polyimides, polyphenylene ethers, and polysulfides. The petroleum resin includes, for example, at least one selected from the group consisting of aromatic petroleum resins and hydrogenated aromatic petroleum resins. A resin may contain at least a binder resin, and the graphite particles (A) may be dispersed in the binder resin.

The thermally conductive sheet preferably contains a polyolefin. A polyolefin can function as a binder resin. For example, a polyolefin includes at least one selected from the group consisting of polyethylene, polypropylene, polybutene, and ethylene-α-olefin copolymer. For example, the thermally conductive sheet contains polybutene.

The thermally conductive sheet preferably contains an acrylic resin. An acrylic resin can function as a binder resin. For example, the thermally conductive sheet contains a (meth)acrylic polymer. In the present disclosure, “(meth)acrylic” is a generic term for “acrylic” and “methacrylic”, and “(meth)acrylate” is a generic term for “acrylate” and “methacrylate”.

The thermally conductive sheet may contain a polyolefin and an acrylic resin, or may contain polybutene and a (meth)acrylic polymer, as a binder resin. When the binder resin contains a polyolefin, from the viewpoint of obtaining good thermal conductivity, the content of polybutene is, for example, 80% by mass or more, 85% by mass or more, 90% by mass or more, 95% by mass or more, or 100% by mass, based on the mass of the polyolefin. When the binder resin contains polybutene and a (meth)acrylic polymer, from the viewpoint of obtaining good thermal conductivity, the total content of the polybutene and (meth)acrylic polymer contained in the binder resin is, for example, 80% by mass or more, 85% by mass or more, 90% by mass or more, 95% by mass or more, or 100% by mass, based on the mass of the binder resin.

The thermally conductive sheet may further contain optional components other than a resin. The thermally conductive sheet may contain one optional component or two or more optional components. Examples of optional components include hot melt agents, antioxidants, flame retardants, toughness modifiers, moisture absorbers, coupling agents, surfactants, ion-trapping agents, and the like.

The binder resin includes, for example, a polymer (B) that is liquid at 25° C., and/or a polymer (C) that has a glass transition temperature of 20° C. or lower. The binder resin includes, for example, a polymer (B) that is liquid at 25° C., and a polymer (C) that has a glass transition temperature of 20° C. or lower.

In some embodiments, the thermally conductive sheet contains graphite particles (A), a polymer (B) that is liquid at 25° C., and a polymer (C) that has a glass transition temperature of 20° C. or lower. In some embodiments, the thermally conductive sheet contains graphite particles (A), a polymer (B) that is liquid at 25° C., a polymer (C) that has glass transition temperature of 20° C. or lower, and a hot melt agent (D) and/or an antioxidant (E). The thermally conductive sheet may further contain a flame retardant.

(Polymer (B) that is Liquid at 25° C.)

The thermally conductive sheet may contain a polymer (B) that is liquid at 25° C. (hereinafter, sometimes simply referred to as “polymer (B)”). When the thermally conductive sheet contains the polymer (B), the flexibility of the thermally conductive sheet improves, and it tends to be possible to reduce the contact thermal resistance of the thermally conductive sheet. When the thermally conductive sheet contains the polymer (B) and the hot melt agent (D), it tends to be possible to further increase the cohesion and fluidity during heating.

In the present disclosure, a “polymer that is liquid at 25° C.” is a polymer that has fluidity at 25° C. A “polymer that is liquid at 25° C.” may be a polymer that has viscous properties at 25° C., and, for example, the viscosity, which is a measure indicating viscous properties, is 0.0001 to 10,000 Pa·s at 25° C. In the present disclosure, viscosity can be measured at 25° C. using a rheometer at a shear rate of 5.0 s−1. The viscosity can be measured at a temperature of 25° C. as a shear viscosity using a rotational shear viscometer mounted with a cone plate (diameter: 40 mm, cone angle:0°). The viscosity of the polymer (B) at 25° C. is, for example, 0.0001 Pa·s or more, 0.001 Pa·s or more, or 0.01 Pa·s or more. The viscosity of the polymer (B) at 25° C. is, for example, 10,000 Pa·s or less, 1,000 Pa·s or less, or 100 Pa·s or less.

As the polymer (B), a resin that is liquid at 25° C. can be selected from the aforementioned examples of resins and used. The polymer (B) includes, for example, at least one selected from the group consisting of polybutene, polyisoprene, polysulfide, silicone, (meth)acrylonitrile polymer, (meth)acrylic polymer, terpene resin, and petroleum resin. When the thermally conductive sheet is to be used in a semiconductor device, the polymer (B) preferably includes at least one selected from the group consisting of polybutene and polyisoprene. In particular, from the viewpoint of suppressing the contact thermal resistance of the thermally conductive sheet, it is preferable that the polymer (B) contain polybutene. When the thermally conductive sheet contains polybutene that is liquid at 25° C., the tackiness of the thermally conductive sheet and the stress mitigation properties tend to improve. The polymer (B) may contain one polymer or two or more polymers.

Polybutene is a polymer obtained by polymerizing a monomer containing isobutene and/or normal butene. Polybutene may be a homopolymer obtained by polymerizing isobutene or normal butene; a copolymer obtained by copolymerizing isobutene and normal butene; or a copolymer obtained by polymerizing a monomer containing isobutene and/or normal butene, and another monomer. Examples of the other monomer include α-olefins such as ethylene, propylene, and styrene. The copolymer may be any of a random copolymer, a block copolymer, or a graft copolymer.

Polybutene is a polymer containing at least one structural unit selected from the group consisting of structural units represented by —[CH₂—C(CH₃)₂]— and structural units represented by —[CH₂—CH(CH₂CH₃)]—. Polybutene may further contain an optional structural unit. Polybutene is sometimes also referred to as polybutylene.

Examples of polybutene include “NOF Polybutene” by NOF Corporation, “Nisseki Polybutene” by JXTG Energy Corporation, “Tetrax” by JXTG Energy Corporation, “Himol” by JXTG Energy Corporation, “Polyisobutylene” by Tomoe Engineering Co., Ltd., and the like.

The content of the polymer (B) in the thermally conductive sheet is, for example, 10% by volume or more, 15% by volume or more, or 20% by volume or more, based on the volume of the thermally conductive sheet. When the content of the polymer (B) is 10% by volume or more, the flexibility, tackiness, and adhesiveness of the thermally conductive sheet tend to further improve. The content of the polymer (B) in the thermally conductive sheet is, for example, 55% by volume or less, 50% by volume or less, or 45% by volume or less, based on the volume of the thermally conductive sheet. When the content of the polymer (B) is 55% by volume or less, the thermally conductive sheet tends to have sufficient strength and thermal conductivity. The content of the polymer (B) is preferably within the above ranges also from the viewpoint of enhancing the tack force, adhesiveness, sheet strength, hydrolysis resistance, and the like.

(Polymer (C) that has a Glass Transition Temperature of 20° C. or Lower)

The thermally conductive sheet may contain a polymer (C) that has a glass transition temperature of 20° C. or lower (hereinafter, sometimes simply referred to as “polymer (C)”). When the thermally conductive sheet contains the polymer (C), the flexibility of the thermally conductive sheet improves, and it tends to be possible to reduce the contact thermal resistance of the thermally conductive sheet. The polymer (C) is a polymer that does not fall under the polymer (B) that is liquid at 25° C. In other words, the polymer (C) is a polymer that has a glass transition temperature of 20° C. or lower and is not liquid at 25° C.

The glass transition temperature (Tg) of the polymer (C) is, for example, 20° C. or lower, 0° C. or lower, or −20° C. or lower. When the glass transition temperature is 20° C. or lower, the flexibility and tackiness of the thermally conductive sheet tend to improve. The glass transition temperature (Tg) of the polymer (C) is, for example, −70° C. or higher, −50° C. or higher, or −30° C. or higher. In the present disclosure, the glass transition temperature (Tg) can be obtained from tan δ measured by dynamic viscoelasticity measurement (tensile). The peak temperature of tan δ can be taken as the glass transition temperature (Tg).

The weight average molecular weight of the polymer (C) is, for example, 100,000 or more, 250,000 or more, or 400,000 or more. When the weight average molecular weight is 100,000 or more, the film strength of the thermally conductive sheet tends to improve. The weight average molecular weight of the polymer (C) is, for example, 1,000,000 or less, 700,000 or less, or 600,000 or less. When the weight average molecular weight is 1,000,000 or less, the flexibility of the thermally conductive sheet tends to improve. The weight average molecular weight can be measured by gel permeation chromatography using a standard polystyrene calibration curve.

As the polymer (C), a resin that has a glass transition temperature of 20° C. or lower can be selected from the aforementioned examples of resins and used. The polymer (C) may include, for example, at least one selected from the group consisting of (meth)acrylic polymers, silicones, and conjugated diene polymers, and preferably includes a (meth)acrylic polymer. Examples of conjugated diene polymers include polybutadiene, polyisoprene, and the like. A (meth)acrylic polymer is a polymer obtained by polymerizing a monomer containing a (meth)acrylic monomer. A (meth)acrylic monomer has at least one (meth)acryloyl group in the molecule. Preferably, the (meth)acrylic monomer contains at least a monomer having a (meth)acryloyloxy group. In the present disclosure, “(meth)acrylic monomer” is a generic term for acrylic monomers and methacrylic monomers, and “(meth)acryloyl group” is a generic term for acryloyl groups and methacryloyl groups. When the thermally conductive sheet contains a (meth)acrylic polymer that has a glass transition temperature of 20° C. or lower, there tends to be an improvement in the tackiness of the thermally conductive sheet and the elasticity such as that with which the thickness is restored to follow warpage. The polymer (C) may contain one polymer or two or more polymers.

Examples of (meth)acrylic monomers include: alkyl (meth)acrylate esters such as butyl (meth)acrylate, ethyl (meth)acrylate, methyl (meth)acrylate, and 2-ethylhexyl (meth)acrylate; (meth)acrylic acid; (meth)acrylate esters having a hydroxyl group such as 2-hydroxy(meth)acrylate; (meth)acrylate esters having a glycidyl group such as glycidyl (meth)acrylate; (meth)acrylic acid; (meth)acrylamide; and the like. The (meth)acrylic polymer may be a homopolymer or a copolymer. The (meth)acrylic polymer is preferably a copolymer, and may be a copolymer of an alkyl (meth)acrylate ester, a (meth)acrylic acid, and (meth)acrylonitrile. As the (meth)acrylic polymer, for example, a (meth)acrylic polymer known as an acrylic rubber can be used.

The content of the polymer (C) in the thermally conductive sheet is, for example, 5% by volume or more, 8% by volume or more, or 10% by volume or more, based on the volume of the thermally conductive sheet. When the content of the polymer (C) is 5% by volume or more, the flexibility, tackiness, and adhesiveness of the thermally conductive sheet tend to further improve. The content of the polymer (C) in the thermally conductive sheet is, for example, 55% by volume or less, 50% by volume or less, 45% by volume or less, 30% by volume or less, or 20% by volume or less, based on the volume of the thermally conductive sheet. When the content of the polymer (C) is 55% by volume or less, the thermally conductive sheet tends to have sufficient strength and thermal conductivity. The content of the polymer (C) is preferably within the above ranges also from the viewpoint of enhancing the tack force, adhesiveness, sheet strength, hydrolysis resistance, and the like.

### (Hot Melt Agent (D))

The thermally conductive sheet may contain a hot melt agent (D). When the thermally conductive sheet contains a hot melt agent (D), the strength of the thermally conductive sheet and the fluidity during heating tend to improve.

The hot melt agent (D) may include, for example, at least one selected from the group consisting of aromatic petroleum resins, hydrogenated aromatic petroleum resins, terpene phenolic resins, hydrogenated terpene phenolic resins, and cyclopentadiene-based petroleum resins. The thermally conductive sheet may contain one hot melt agent (D) or two or more hot melt agents (D). In particular, when the thermally conductive sheet contains the hot melt agent (D) and the polymer (B) containing polybutene, the hot melt agent (D) preferably contains at least one selected from the group consisting of hydrogenated aromatic petroleum resins and hydrogenated terpene phenolic resins. Hydrogenated aromatic petroleum resins and hydrogenated terpene phenolic resins have high stability and excellent compatibility with polybutene, and therefore tend to be able to achieve better thermal conductivity, flexibility, and ease of handling.

Examples of hydrogenated aromatic petroleum resins include “ARKON” manufactured by Arakawa Chemical Industries, Ltd., “I-MARV” manufactured by Idemitsu Kosan Co., Ltd., and the like. Furthermore, examples of hydrogenated terpene phenolic resins include CLEARON manufactured by Yasuhara Chemical Co., Ltd. and the like. Furthermore, examples of cyclopentadiene-based petroleum resins include “Quintone” manufactured by Zeon Corporation, “Marcaretz” manufactured by Maruzen Petrochemical, and the like.

The hot melt agent (D) may be solid at 25° C. and have a softening temperature of 40° C. to 150° C. When the hot melt agent (D) contains a thermoplastic resin, fluidity during thermocompression bonding improves, and as a result adhesiveness tends to improve. When the softening temperature is 40° C. or higher, cohesion near room temperature can be maintained, which makes it easier to obtain sufficient sheet strength, and the ease of handling tends to be superior. When the softening temperature is 150° C. or lower, fluidity during thermocompression bonding increases, and therefore adhesiveness tends to improve. The softening temperature is more preferably 60° C. to 120° C. The softening temperature can be measured according to the ring-and-ball method (JIS K 2207:1996).

The content of the hot melt agent (D) in the thermally conductive sheet is, for example, 3 to 25% by volume, 5 to 20% by volume, or 5 to 15% by volume, based on the volume of the thermally conductive sheet, from the viewpoint of increasing the tack force, adhesiveness, sheet strength, and the like. When the content of the hot melt agent (D) is 3% by volume or more, the tack force, fluidity during heating, sheet strength, and the like tend to be sufficient. When the content of the hot melt agent (D) is 25% by volume or less, the flexibility is sufficient, and therefore the ease of handling and thermal cycle resistance tend to be superior.

### (Antioxidant (E))

The thermally conductive sheet may contain an antioxidant (E). When the thermally conductive sheet contains an antioxidant (E), the thermal stability at high temperatures tends to improve.

The antioxidant (E) may include, for example, at least one selected from the group consisting of phenol-based antioxidants, phosphorus-based antioxidants, amine-based antioxidants, sulfur-based antioxidants, hydrazine-based antioxidants, and amide-based antioxidants. The thermally conductive sheet may contain one antioxidant (E) or two or more antioxidants (E). The antioxidant (E) can be selected as appropriate in accordance with temperature conditions or the like under which the antioxidant (E) is to be used. The antioxidant (E) includes a phenol-based antioxidant, for example. A phenol-based antioxidant can include a hindered phenol-based antioxidant as an example.

Examples of phenol-based antioxidants include “ADK STAB AO-50”, “ADK STAB AO-60”, and “ADK STAB AO-80” manufactured by Adeka Corporation, and the like.

The content of the antioxidant (E) in the thermally conductive sheet is, for example, 0.1 to 5% by volume, 0.2 to 3% by volume, or 0.3 to 1% by volume, based on the volume of the thermally conductive sheet. When the content of the antioxidant (E) is 0.1% by volume or more, an antioxidation effect tends to be sufficiently obtained. When the content of the antioxidant (E) is 5% by volume or less, a sufficient strength of the thermally conductive sheet tends to be obtained.

### (Flame Retardant)

For example, the thermally conductive sheet may contain a flame retardant from the viewpoint of flame retardance. The flame retardant is not particularly limited and can be selected as appropriate from commonly used flame retardants. Examples of flame retardants include red phosphorus-based flame retardants, phosphate ester-based flame retardants, and the like. A phosphate ester-based flame retardant is preferable from the viewpoints of excellent safety and improved adhesiveness due to the plasticization effect.

Examples of phosphate ester-based flame retardants include: aliphatic phosphate esters such as trimethyl phosphate, triethyl phosphate, and tributyl phosphate; aromatic phosphate esters such as triphenyl phosphate, tricresyl phosphate, and cresyl diphenyl phosphate; and aromatic condensed phosphate esters such as resorcinol bisdiphenyl phosphate, bisphenol A bis(diphenyl phosphate), and resorcinol bisdixylenyl phosphate.

The content of the flame retardant in the thermally conductive sheet is, for example, based on the volume of the thermally conductive sheet, 30% by volume or less, and from the viewpoint of preventing flame retardant components from seeping out onto the surface of the thermally conductive sheet, 20% by volume or less.

### [Thickness]

The thickness of the thermally conductive sheet can be selected according to usage. The thickness of thermally conductive sheets is, for example, 500 μm or less, 400 μm or less, 320 μm or less, 300 μm or less, 280 μm or less, 250 μm or less, 230 μm or less, 200 μm or less, 180 μm or less, 150 μm or less, or 130 μm or less. When the thermally conductive sheet has reduced thickness, the bulk thermal resistance can be suppressed, and the effect of improved thermal conductivity tends to be easily obtained. The thickness of the thermally conductive sheet is, for example, 50 μm or more, 80 μm or more, 100 μm or more, 110 μm or more, or 120 μm or more, from the viewpoint of ease of handling. When the thickness of the thermally conductive sheet is 280 μm or less, a particularly high improvement in thermal conductivity tends to be obtained. The thickness of the thermally conductive sheet can be obtained as the arithmetic mean value of measurement values obtained by measuring the thickness of the thermally conductive sheet at any three locations using a micrometer at room temperature (25° C.).

### [Compression Ratio]

The thickness compression ratio of the thermally conductive sheet is, for example, 24% or more. In some embodiments, the compression ratio of the thermally conductive sheet is measured at a temperature of 150° C. and a compressive stress of 0.14 MPa. Alternatively, in some embodiments, the compression ratio of the thermally conductive sheet is measured at the temperature and compressive stress at which the heat generating body and the heat dissipating body are adhered via the thermally conductive sheet. The temperature and compressive stress at which the heat generating body and the heat dissipating body are adhered via the thermally conductive sheet will be described below. In the present disclosure, “compression ratio” is the ratio (percentage (%)) of the amount of compression (μm) with respect to the thickness (μm) of the thermally conductive sheet before applying pressure (compression ratio (%)=amount of compression (μm)/thickness (μm) of thermally conductive sheet before applying pressure×100). The thickness of the thermally conductive sheet before applying pressure is the thickness at room temperature (25° C.) obtained using the aforementioned method using a micrometer.

The compression ratio of the thermally conductive sheet is, for example, 24% or more, 25% or more, 28% or more, 30% or more, 35% or more, 40% or more, 43% or more, or 44% or more. When the compression ratio of the thermally conductive sheet is large, the contact thermal resistance can be suppressed, and the effect of improved thermal conductivity tends to be easily obtained. This effect is more prominent as the thickness of the thermally conductive sheet decreases and/or the pressure during adhesion decreases. The compression ratio of the thermally conductive sheet is, for example, 60% or less, 55% or less, or 50% or less, from the viewpoint of ease of handling. When the compression ratio of the thermally conductive sheet is 24% or more, a particularly high improvement in thermal conductivity tends to be obtained.

In the present disclosure, the “amount of compression” is the amount of compression of the thermally conductive sheet obtained by applying pressure in the thickness direction of the thermally conductive sheet. The amount of compression can be measured using the following method. The thermally conductive sheet is heated to 150° C., a load is applied in the thickness direction at a displacement rate of 0.1 mm/min, and the displacement (mm) and load (N) are measured. The displacement (mm) when the stress is 0.14 MPa is taken as the amount of compression (μm).

The amount of compression of the thermally conductive sheet is, for example, 30 μm or more, 40 μm or more, 45 μm or more, or 50 μm or more. When the amount of compression of the thermally conductive sheet is large, the effect of improved thermal conductivity tends to be easily obtained. The amount of compression of the thermally conductive sheet is, for example, 100 μm or less, 90 μm or less, 80 μm or less, 70 μm or less, or 60 μm or less, or 55 μm or less, from the viewpoints of ease of handling and improved thermal conductivity. For example, when the thickness of the thermally conductive sheet is 280 μm or less, the amount of compression is preferably 45 μm or more.

The compression ratio can be adjusted by varying the ratio of the mean particle diameter of the graphite particles (A), the components of the thermally conductive sheet, or the like described below. For example, a large compression ratio tends to be obtained when the ratio of the mean particle diameter is 75% or less. For example, when the thermally conductive sheet contains the polymer (B) and the polymer (C) as a binder, a large compression ratio tends to be obtained.

### [Ratio of Mean Particle Diameter of Graphite Particles (A) to Thickness]

In the thermally conductive sheet, the mean particle diameter of the graphite particles (A) is, for example, 50-75% with respect to the thickness of the thermally conductive sheet. In the present disclosure, the ratio (percentage (%)) of the mean particle diameter (μm) of the graphite particles (A) with respect to the thickness (μm) of the thermally conductive sheet may be simply described as the “ratio of the mean particle diameter” (ratio (%) of mean particle diameter=mean particle diameter (μm) of graphite particles (A)/thickness (μm) of thermally conductivesheet×100).

The ratio of the mean particle diameter is, for example, 50% or more, 55% or more, 60% or more, 65% or more, or 68% or more. When the ratio of the mean particle diameter is 50% or more, bulk thermal resistance can be suppressed, and the effect of improved thermal conductivity tends to be easily obtained. The ratio of the mean particle diameter is, for example, 75% or less, 73% or less, or 70% or less. When the ratio of the mean particle diameter is 75% or less, the contact thermal resistance can be suppressed, and the effect of improved thermal conductivity tends to be easily obtained. This effect is more prominent as the thickness of the thermally conductive sheet decreases and/or the pressure during adhesion decreases.

### [Surface Roughness (Ra)]

The arithmetic mean roughness (Ra) of the surface of the thermally conductive sheet is, for example, 8.0 μm or less. In the present disclosure, the arithmetic mean roughness (Ra) of the surface can be measured using the following method. First, any five locations are selected from the surface of the thermally conductive sheet. At each location, the surface is analyzed along two diagonal lines of a 40 mm×30 mm rectangle, and the arithmetic mean roughness (Ra) is measured. The arithmetic mean value obtained from 10 measurement values (5 locations×2 diagonal lines) obtained is taken as the arithmetic mean roughness (Ra) of the surface of the thermally conductive sheet. The arithmetic mean roughness (Ra) of each diagonal line can be measured using a 3D shape measuring device (for example, 12× magnification).

The arithmetic mean roughness (Ra) is, for example, 8.0 μm or less, 7.5 μm or less, 7.0 μm or less, or 6.5 μm or less. When the arithmetic mean roughness (Ra) is 8.0 μm or less, the contact thermal resistance can be suppressed, and the effect of improved thermal conductivity tends to be easily obtained. The lower limit of the arithmetic mean roughness (Ra) is not particularly limited. The arithmetic mean roughness (Ra) is, for example, 1.0 μm or more, 2.0 μm or more, or 3.0 μm or more.

The arithmetic mean roughness (Ra) can be adjusted by varying the mean particle diameter of the graphite particles (A), the ratio of the mean particle diameter of the graphite particles (A), and the like. For example, the arithmetic mean roughness (Ra) tends to decrease as the mean particle diameter decreases. For example, when the ratio of the mean particle diameter is 75% or less, a low arithmetic mean roughness (Ra) tends to be obtained.

### [Elastic Modulus]

The elastic modulus (compression modulus) of the thickness of the thermally conductive sheet is, for example, 0.60 MPa or less at a temperature of 150° C. and a compressive stress of 0.03 MPa. In the present disclosure, the elastic modulus can be measured using the following method. The thermally conductive sheet is heated to 150° C., a load is applied in the thickness direction at a displacement rate of 0.1 mm/min, and the displacement (mm) and load (N) are measured. The strain (dimensionless) obtained as displacement (mm)/thickness (mm) is plotted on a horizontal axis, the stress (MPa) determined as load (N)/area (mm²) is plotted on a vertical axis, and the slope at a stress of 0.03 MPa is taken as the elastic modulus (MPa). A compression testing device can be used for the measurement.

The elastic modulus is, for example, 0.60 MPa or less, 0.55 MPa or less, 0.50 MPa or less, 0.40 MPa or less, or 0.35 MPa or less. When the elastic modulus is 0.60 MPa or less, the contact thermal resistance can be suppressed, and the effect of improved thermal conductivity tends to be easily obtained. The lower limit of the elastic modulus is not particularly limited. The elastic modulus is, for example, 0.10 MPa or more, 0.20 MPa or more, or 0.25 MPa or more, from the viewpoint of ease of handling.

The elastic modulus can be adjusted by varying the thickness of the thermally conductive sheet, the ratio of the mean particle diameter of the graphite particles (A), and the like. For example, the elastic modulus tends to decrease as the thickness of the thermally conductive sheet decreases. For example, when the thickness of the thermally conductive sheet is approximately the same, the elastic modulus tends to decrease as the ratio of the mean particle diameter of the graphite particles (A) decreases.

### [Protective Film]

At least one surface or both surfaces of the thermally conductive sheet may be protected by a protective film. Examples of a protective film include: resin films of polyethylene, polyester, polypropylene, polyethylene terephthalate, polyimide, polyetherimide, polyethernaphthalate, methylpentene, or the like; metal foil such as aluminum; coated paper; coated fabric; and the like. The protective film may be a single-layer film or a multilayer film. The protective film may be surface treated with a silicone-based, silica-based, or other release agent.

### [Manufacturing Method]

The method of manufacturing the thermally conductive sheet is not particularly limited. The method of manufacturing the thermally conductive sheet includes, for example: preparing a composition containing the graphite particles (A) and optional components; producing a sheet using the composition; layering a plurality of sheets to produce a layered body; and slicing a side end surface of the layered body to obtain a thermally conductive sheet. The method of manufacturing the thermally conductive sheet may additionally include affixing a protective film to the thermally conductive sheet obtained by slicing. According to this manufacturing method, it is possible to easily manufacture a thermally conductive sheet in which the graphite particles (A) are oriented in the thickness direction.

Preparing the composition may be mixing the graphite particles (A) an optional component such as a resin to obtain the composition. The mean particle diameter of the graphite particles (A) before mixing is, for example, 100 μm or more, 150 μm or more, or 200 μm or more, from the viewpoint of obtaining good thermal conductivity. The mean particle diameter of the graphite particles (A) before mixing is 500 μm or less, 400 μm or less, or 300 μm or less. The graphite particles (A) preferably have a particle diameter of less than 1,000 μm, in other words, the graphite particles (A) preferably do not contain particles having a particle diameter of 1,000 μm or more.

The mean particle diameter of the graphite particles (A) before mixing can be measured using a sieving method. Sieves with nominal openings of 1,000 μm, 850 μm, 710 μm, 600 μm, 500 μm, 425 μm, 300 μm, 212 μm, and 106 μm are used for sieving. To begin, all of the graphite particles (A) are passed through the sieve having a nominal opening of 1,000 μm, and the fraction obtained on the sieve having a nominal opening of 1,000 μm is confirmed to be 0 g. Thereafter, sieving is performed using the sieves having nominal openings from 850 μm to 106 μm in sequence, and thereafter the mean particle diameter of the graphite particles (A) before mixing is calculated from the mass percentage (%) of each fraction with respect to the total of the fractions, and the particle diameter of each fraction. For example, the particle diameter of the fraction remaining on the sieve having a nominal opening of 850 μm is taken as 925 μm ((1,000+850)/2). Particle diameters obtained using the same method are used also for the fractions remaining on the sieves having nominal openings of 710 to 212 μm. The particle diameter of the fraction that has passed through the nominal opening of 106 μm is taken as 53 μm ((106+0)/2). The mean particle diameter of the graphite particles (A) before mixing can be obtained by calculating, for each fraction, the particle diameter (μm) of the fraction×the mass percentage (%) of the fraction, and totaling the obtained values.

The mean particle diameter of the graphite particles (A) before mixing is, for example, less than or equal to 2.5 times, less than or equal to 2.3 times, or less than or equal to 2.1 times the thickness of the thermally conductive sheet. The mean particle diameter of the graphite particles (A) is, for example, greater than or equal to 0.6 times, greater than or equal to 0.7 times, or greater than or equal to 0.8 times the thickness of the thermally conductive sheet.

A sheet may be produced using, for example, at least one forming method selected from the group consisting of rolling, pressing, extruding, and coating. The layered body may be produced by, for example, superposing a plurality of independent sheets in sequence, may be produced by folding one sheet, or may be produced by winding one sheet.

A cutting tool such as a slicer or a knife can be used for slicing. Preferably, a side end surface of the layered body is sliced at an angle of 0° to 30° to the normal line exiting from the main surface of the layered body, so as to obtain a thermally conductive sheet having a desired thickness.

<Device Provided with Heat Generating Body and Heat Dissipating Body>

The aforementioned thermally conductive sheet can be used in a device provided with a heat generating body and a heat dissipating body. For example, the device includes a heat generating body and a heat dissipating body, and a thermally conductive sheet in contact with the heat generating body and the heat dissipating body. The device may be a layered body that includes a heat generating body, a thermally conductive sheet, and a heat dissipating body. Owing to the thermally conductive sheet, it is possible for heat from the heat generating body to be efficiently conducted to the heat dissipating body. When it is possible for heat to be efficiently conducted, the life of the device improves, and the device is able to function stably even for long period of use. The temperature range in which the thermally conductive sheet can be used particularly favorably is −10 to 150° C., for example.

Examples of the heat generating body include semiconductor chips, semiconductor devices, displays, LEDs, LED devices, electric lights, semiconductor modules, power modules for automobiles, power modules for industrial use, and the like. The heat generating body may include, for example, at least one selected from the group consisting of semiconductor chips and semiconductor devices.

Examples of the heat dissipating body include: aluminum or copper heat spreaders; heat sinks utilizing aluminum or copper fins, plates, or the like; aluminum or copper blocks connected to heat pipes; aluminum or copper blocks inside which a cooling liquid is circulated by a pump; Peltier elements and aluminum or copper blocks provided with Peltier elements; and the like.

The method of manufacturing the device is not particularly limited. The method of manufacturing the device includes, for example: arranging the aforementioned thermally conductive sheet to be between a heat generating body and a heat dissipating body, and obtaining a composite body including the heat generating body, the heat dissipating body, and the thermally conductive sheet in contact with the heat generating body and the heat dissipating body; and applying pressure in the thickness direction of the thermally conductive sheet to the composite body, and adhering the heat generating body and the heat dissipating body via the thermally conductive sheet. The pressure applied to the composite body is, for example, 0.05 MPa or more, 0.10 MPa or more, or 0.12 MPa or more. The pressure applied to the composite body is, for example, 0.30 MPa or less, 0.20 MPa or less, or 0.15 MPa or less. A fixing implement, a pressing machine, or the like can be used for applying pressure. The aforementioned thermally conductive sheet is able to exhibit good thermal conductivity even when adhered under low pressure.

The composite body is preferably heated when applying pressure. Heating can be performed by heating the heat generating body or by using an oven, a pressing machine, or the like. The heating temperature is, for example, 80° C. or higher, 100° C. or higher, or 120° C. or higher. The heating temperature is, for example, 180° C. or lower, 170° C. or lower, or 160° C. or lower.

Examples of conditions for adhesion include: a pressure of 0.05 to 0.30 MPa and a temperature of 80 to 160° C.; a pressure of 0.10 to 0.20 MPa and a temperature of 100 to 170° C.; a pressure of 0.12 to 0.15 MPa and a temperature of 120 to 160° C.; or the like.

Examples of devices provided with a heat generating body and a heat dissipating body include semiconductor devices, displays, LED devices, electric lights, semiconductor modules, power modules for automobiles, power modules for industrial use, and the like.

### Examples of Embodiments

Preferred examples of embodiments of the present invention are given below. Embodiments of the present invention are not limited to the following examples.

(1) A thermally conductive sheet containing graphite particles (A) including at least one selected from the group consisting of flake-like particles, ellipsoidal particles, and cylindrical particles, in which the graphite particles (A) are oriented in a thickness direction, and a thickness compression ratio is 24% or more at a temperature of 150° C. and a compressive stress of 0.14 MPa.

(2) A thermally conductive sheet containing graphite particles (A) including at least one selected from the group consisting of flake-like particles, ellipsoidal particles, and cylindrical particles, in which the graphite particles (A) are oriented in a thickness direction, and a mean particle diameter of the graphite particles (A) is 50 to 75% of a thickness.

(3) The thermally conductive sheet according to the aforementioned (1), in which a mean particle diameter of the graphite particles (A) is 50 to 75% of a thickness of the thermally conductive sheet.

(4) The thermally conductive sheet according to any one of the aforementioned (1) to (3), in which an arithmetic mean roughness of a surface is 8.0 μm or less.

(5) The thermally conductive sheet according to any one of the aforementioned (1) to (4), in which a thickness is 320 μm or less.

(6) The thermally conductive sheet according to any one of the aforementioned (1) to (5), further containing a polymer (B) that is liquid at 25° C.

(7) The thermally conductive sheet according to the aforementioned (6), in which the polymer (B) contains polybutene.

(8) The thermally conductive sheet according to any one of the aforementioned (1) to (7), further containing a polymer (C) that has a glass transition temperature of 20° C. or lower.

(9) The thermally conductive sheet according to the aforementioned (8), in which the polymer (C) includes a (meth)acrylic polymer.

(10) The thermally conductive sheet according to any one of the aforementioned (1) to (9), in which the graphite particles (A) include flake-like particles.

(11) A device including a heat generating body, a heat dissipating body, and the thermally conductive sheet according to any one of the aforementioned (1) to (10) in contact with the heat generating body and the heat dissipating body.

(12) The device according to the aforementioned (11), in which the heat generating body includes at least one selected from the group consisting of a semiconductor chip and a semiconductor device.

(13) A method of manufacturing a device, including: arranging the thermally conductive sheet according to any one of the aforementioned (1) to (10) to be between a heat generating body and a heat dissipating body, and obtaining a composite body including the heat generating body, the heat dissipating body, and the thermally conductive sheet in contact with the heat generating body and the heat dissipating body; and applying pressure in a thickness direction of the thermally conductive sheet to the composite body, and adhering the heat generating body and the heat dissipating body via the thermally conductive sheet.

(14) The method of manufacturing according to the aforementioned (13), in which the heat generating body includes at least one selected from the group consisting of a semiconductor chip and a semiconductor device.

### EXAMPLES

Embodiments of the present invention will be described below in further detail by means of examples. The embodiments of the present invention are not limited to the following examples.

### <Producing the Thermally Conductive Sheet>

### Example 1

A composition was obtained by adding the graphite particles (A)-1, polymer (B)-1, polymer (B)-2, polymer (C), hot melt agent (D), and antioxidant (E) described below into a kneading device (“DS3-SGHM-E Pressurized Double-Arm Kneader” manufactured by Moriyama Co., Ltd.) and kneading at a temperature of 150° C. such that the volume fraction of each component with respect to the total becomes 32.3% by volume, 29.0% by volume, 13.4% by volume, 10.2% by volume, 14.6% by volume, and 0.5% by volume, respectively. The volume fraction was obtained according to the aforementioned method of calculating the content (% by volume) using the relative density (density) below.
Graphite Particles (A)-1:
Flake-like expanded graphite particles (manufactured by Hitachi Chemical Company, Ltd., relative density 2.1, mean particle diameter 241 μm)
Polymer (B)-1:
Isobutene-normal butene copolymer (“NOF Polybutene, Grade 30N” manufactured by NOF Corporation, relative density 0.90, liquid at 25° C.)
Polymer (B)-2:
Isobutene homopolymer (“Tetrax 6T” manufactured by Nippon Oil Corporation, relative density 0.92, liquid at 25° C.)
Polymer (C):
Acrylate ester copolymer resin (manufactured by Nagase ChemteX Corporation, butyl acrylate/ethyl acrylate/acrylonitrile/acrylate copolymer, weight average molecular weight: 530,000, Tg=−39° C., relative density: 1.06)
Hot Melt Agent (D):
Hydrogenated petroleum resin (“ARKON P90” manufactured by Arakawa Chemical Industries, Ltd., relative density: 0.99)
Antioxidant (E):
Hindered phenol-based antioxidant (“ADK STAB AO-60” manufactured by Adeka Corporation, relative density: 1.15)

For the graphite particles (A)-1, it was confirmed that the six-membered ring plane within the crystal of the expanded graphite particles was oriented in the plane direction of the flake-like particles, by means of a method using X-ray diffraction measurement described above.

The mean particle diameter of the graphite particles (A)-1 was measured according to the method described above. Specifically, 1.7 g of the graphite particles (A)-1 was classified using sieves having nominal openings of 1,000 μm, 850 μm, 710 μm, 600 μm, 500 μm, 425 μm, 300 μm, 212 μm, and 106 μm. The mass of the fraction remaining on each sieve was measured. A fraction was not obtained (0% by mass) on the nominal opening of 1,000 μm. The mean particle diameter of the graphite particles (A)-1 was obtained with the particle diameters of the fractions remaining on each sieve as 925 μm, 780 μm, 655 μm, 550 μm, 462 μm, 362 μm, 256 μm, 159 μm, and 53 μm, respectively.

Next, the composition obtained by kneading was placed in an extrusion molding machine (“HKS40-15 Extruder” manufactured by Parker Corporation) and extruded into a flat sheet shape having a width of 20 cm and a thickness of 1.5 to 1.6 mm to obtain a sheet. The obtained sheet was press-punched using a 40 mm×150 mm die blade, 61 punched sheets were layered, pressure was applied at 90° C. for 30 minutes in the layering direction with an 80-mm high spacer therebetween, and a 40 mm×150 mm×80 mm layered body was obtained. The mean particle diameter of the graphite particles (A) in the layered body was 177 μm. Thereafter, an 80 mm×150 mm side end surface of the layered body was sliced using a wood slicer, and a thermally conductive sheet was obtained.

The thickness of the thermally conductive sheet was 122 μm. The thickness was obtained by measuring the thickness at any three locations using a micrometer (“406-250-30” manufactured by Mitutoyo Corporation) according to the method described above and obtaining the arithmetic mean.

The graphite particles (A)-1 were oriented in the thickness direction of the thermally conductive sheet, and the orientation angle was 82°. Confirmation of the orientation direction and measurement of the orientation angle were performed according to the aforementioned method using an SEM (“SU5000” manufactured by Hitachi High-Tech Corporation).

The mean particle diameter of the graphite particles (A)-1 included in the thermally conductive sheet was 84 μm, and the ratio of the mean particle diameter was 69%. The mean particle diameter of the graphite particles (A)-1 was measured according to the method described above. Specifically, the thermally conductive sheet was repeatedly dissolved and washed using acetone and butyl acetate, components other than the graphite particles (A)-1 were removed from the thermally conductive sheet, and the graphite particles (A)-1 were obtained. Next, the graphite particles (A)-1 were thoroughly dried in an oven at 150° C. Using a scanning electron microscope (“SU5000” manufactured by Hitachi High-Tech Corporation), 200 particles were randomly selected from the obtained graphite particles (A)-1, and the plane of each particle was observed to measure the major diameter. The arithmetic mean value obtained from the major diameters of the 200 particles obtained was taken as the mean particle diameter of the graphite particles (A)-1. Furthermore, the median diameter (D50) based on the number of particles was obtained from the major diameters of the 200 particles obtained. Note that the mean particle diameter of the graphite particles (A)-1 included in the aforementioned layered body was also measured using the same method. The ratio of the mean particle diameter (%) was calculated from the thickness (μm) of the thermally conductive sheet before compression and the mean particle diameter (μm) of the graphite particles (A)-1.

The compression ratio of the thermally conductive sheet was 44% and the elastic modulus was 0.32. A compression testing device (INSTRON 5948 Micro Tester (INSTRON)) having an attached thermostatic chamber was used to measure the elastic modulus. A thermally conductive sheet was cut into a circular shape 14 mm in diameter and used for testing. The thermally conductive sheet was arranged between pieces of 0.1 mm-thick paper (release paper), to which a load was applied in the thickness direction of the thermally conductive sheet at a displacement rate of 0.1 mm/min in the thermostatic chamber at a temperature of 150° C., and the displacement (mm) and the load (N) were measured. The strain (dimensionless) obtained as displacement (mm)/thickness (mm) was plotted on a horizontal axis, the stress (MPa) obtained as load (N)/area (mm²) was plotted on a vertical axis, and the slope at a stress of 0.03 MPa was taken as the elastic modulus (MPa). Furthermore, the displacement when compressed at a stress of 0.14 MPa was taken as the amount of compression (μm). The compression ratio (%) was calculated from the thickness (μm) of the thermally conductive sheet before compression and the amount of compression

The arithmetic mean roughness (Ra) of the surface of the thermally conductive sheet was 5.0 μm. The arithmetic mean roughness (Ra) was obtained by measuring the Ra at any five locations using a 3D shape measuring device (“VR-3200” manufactured by Keyence Corporation) according to the aforementioned method and determining the arithmetic mean of the 10 measurement values obtained.

### Examples 2 and 3

Thermally conductive sheets were produced in the same way as in Example 1, with the exception of changing the thickness of the thermally conductive sheets. In Example 2, the thickness was 204 μm, and in Example 3, the thickness was 303 μm. The thickness, orientation angle, and the like of the obtained thermally conductive sheets were measured using the same method as in Example 1. The measurement results are shown in Table 1.

### Comparative Examples 1 to 3

Thermally conductive sheets were produced using the same method as in Examples 1 to 3, with the exception of using graphite particles (A)-2 (flake-like expanded graphite particles (manufactured by Hitachi Chemical Company, Ltd., relative density: 2.1, mean particle diameter: 568 μm, mass of fraction remaining on sieve having particle diameter of 1,000 μm: 0% by mass)) instead of the graphite particles (A)-1. The thickness, orientation angle, and the like of the obtained thermally conductive sheets were measured using the same method as in Example 1. The measurement results are shown in Table 1.

### <Evaluation of Thermally Conductive Sheet>

### [Measurement of Thermal Resistance]

A thermally conductive sheet was cut into a 10 mm² piece and arranged between a transistor (2SC2233) and a copper block, constituting a heat generating body and a heat dissipating body, respectively. A current was supplied while pressing the transistor at a pressure of 0.14 MPa at 80° C., at which time the transistor temperature T1 (° C.) and the copper block temperature T2 (° C.) were measured. A thermal resistance value X (K·cm²/W) per unit area (1 cm²) was calculated from the measurement values and an applied electric power W1 (W) using the formula below. The results are shown in Table 1.

X=(T1−T2)×1/W1

TABLE 1

| | | | | | Comparitive | Comparitive | Comparitive |
|---|---|---|---|---|---|---|---|
| Item | Unit | Example 1 | Example 2 | Example 3 | Example 1 | Example 2 | Example 3 |
| Thickness of | μm | 122 | 204 | 303 | 124 | 202 | 301 |
| thermally conductive sheet | | | | | | | |
| Orientation angle of | ° | 82 | 83 | 84 | 82 | 83 | 84 |
| graphite particles (A) | | | | | | | |
| Mean particle diameter of | μm | 84 | 135 | 166 | 97 | 162 | 241 |
| graphite particles (A) | | | | | | | |
| D50 of | μm | 78 | 133 | 152 | 88 | 156 | 242 |
| graphite particles (A) | | | | | | | |
| Ratio of | % | 69 | 66 | 55 | 78 | 80 | 80 |
| mean particle diameter | | | | | | | |
| Amount of compression | μm | 54 | 60 | 73 | 29 | 42 | 58 |
| Compression ratio | % | 44 | 29 | 24 | 23 | 21 | 19 |
| Elastic modulus | MPa | 0.32 | 0.55 | 0.58 | 0.42 | 0.58 | 0.67 |
| Arithmetic | μm | 5.0 | 5.5 | 6.1 | 8.4 | 8.9 | 9.2 |
| mean roughness (Ra) | | | | | | | |
| Thermal resistance | K · cm²/W | 0.125 | 0.140 | 0.164 | 0.197 | 0.179 | 0.171 |

As shown in Table 1, the thermally conductive sheets of Examples 1 to 3 exhibited low thermal resistance and good thermal conductivity compared to the thermally conductive sheets of Comparative Examples 1 to 3. In the thermally conductive sheets of Examples 1 to 3, it is thought that the contact thermal resistance was able to be reduced even when adhered at a low pressure of 0.14 MPa, due to reasons such as the compression ratio being 24% or more, the ratio of the mean particle diameter (mean particle diameter of the graphite particles (A) in the thermally conductive sheet/thickness of the thermally conductive sheet×100) being 50 to 75%, or the arithmetic mean roughness (Ra) of the surface being 8.0 μm or less. Furthermore, the thermally conductive sheet of Example 1 exhibited particularly excellent thermal conductivity. The thermally conductive sheet of Example 1 is thought to also have reduced bulk thermal resistance owing to its reduced thickness.

1. A thermally conductive sheet comprising graphite particles (A) including at least one selected from the group consisting of flake-like particles, ellipsoidal particles, and cylindrical particles, wherein
the graphite particles (A) are oriented in a thickness direction, and
a thickness compression ratio is 24% or more at a temperature of 150° C. and a compressive stress of 0.14 MPa.

2. The thermally conductive sheet according to claim 1, wherein an arithmetic mean roughness of a surface is 8.0 μm or less.

3. A thermally conductive sheet comprising graphite particles (A) including at least one selected from the group consisting of flake-like particles, ellipsoidal particles, and cylindrical particles, wherein
the graphite particles (A) are oriented in a thickness direction, and
a mean particle diameter of the graphite particles (A) is 50 to 75% of a thickness.

4. The thermally conductive sheet according to claim 1, wherein a thickness is 320 μm or less.

5. The thermally conductive sheet according to claim 1, further comprising a polymer (B) that is liquid at 25° C.

6. The thermally conductive sheet according to claim 5, wherein the polymer (B) contains polybutene.

7. The thermally conductive sheet according to claim 1, further comprising a polymer (C) that has a glass transition temperature of 20° C. or lower.

8. The thermally conductive sheet according to claim 7, wherein the polymer (C) includes a (meth)acrylic polymer.

9. The thermally conductive sheet according to claim 1, wherein the graphite particles (A) include flake-like particles.

10. A device comprising a heat generating body, a heat dissipating body, and the thermally conductive sheet according to claim 1 in contact with the heat generating body and the heat dissipating body.

11. The device according to claim 10, wherein the heat generating body includes at least one selected from the group consisting of a semiconductor chip and a semiconductor device.

12. A method of manufacturing a device, comprising:
arranging the thermally conductive sheet according to claim 1 to be between a heat generating body and a heat dissipating body, and obtaining a composite body including the heat generating body, the heat dissipating body, and the thermally conductive sheet in contact with the heat generating body and the heat dissipating body; and
applying pressure in a thickness direction of the thermally conductive sheet to the composite body, and adhering the heat generating body and the heat dissipating body via the thermally conductive sheet.

13. The method of manufacturing according to claim 12, wherein the heat generating body includes at least one selected from the group consisting of a semiconductor chip and a semiconductor device.

14. The thermally conductive sheet according to claim 3, wherein a thickness is 320 or less.

15. The thermally conductive sheet according to claim 3, further comprising a polymer (B) that is liquid at 25° C.

16. The thermally conductive sheet according to claim 15, wherein the polymer (B) contains polybutene.

17. The thermally conductive sheet according to claim 3, further comprising a polymer (C) that has a glass transition temperature of 20° C. or lower.

18. The thermally conductive sheet according to claim 17, wherein the polymer (C) includes a (meth)acrylic polymer.

19. A device comprising a heat generating body, a heat dissipating body, and the thermally conductive sheet according to claim 3 in contact with the heat generating body and the heat dissipating body.

20. A method of manufacturing a device, comprising:
arranging the thermally conductive sheet according to claim 3 to be between a heat generating body and a heat dissipating body, and obtaining a composite body including the heat generating body, the heat dissipating body, and the thermally conductive sheet in contact with the heat generating body and the heat dissipating body; and
applying pressure in a thickness direction of the thermally conductive sheet to the composite body, and adhering the heat generating body and the heat dissipating body via the thermally conductive sheet.
